(19) United States
(12) Patent Application Publication
(10) Pub. No.: US 2002/0029365 A1
(43) Pub. Date: Mar. 7, 2002

(54) Information processing apparatus

(76) Inventors: Yoshimichi Sato, Hitachi-shi (JP); Shoji Yoshida, Hitachi-shi (JP); Shigeya Tanaka, Hitachi-shi (JP); Takashi Hotta, Hitachi-shi (JP); Yuji Sugaya, Hitachinaka-shi (JP)

Correspondence Address: KENYON & KENYON, 1500 K STREET, N.W., SUITE 700, WASHINGTON, DC, 20005, US

(21) Appl. No.: 09/925,606

(22) Filed: Aug. 10, 2001

Related U.S. Application Data
(63) Continuation of application No. 09/202,561, filed on Dec. 17, 1998.
Application No. 09/202,561 is a 371 of international application No. PCT/JP96/01839, filed on Jul. 3, 1996.

(51) Int. Cl. G11C 29/00

(52) U.S. Cl. 714/763

(57) ABSTRACT

An information processing apparatus having a CPU, a memory and a memory controller. The CPU includes a burst access interface for rapidly transferring data, and a single access interface for partial write operations. The memory controller comprises two ECC controllers, one for burst access and the other for single access. Either burst access mode or single access mode can be selected, so that both ECC-based high reliability and a high-speed memory access capability are made available.

### TECHNICAL FIELD

The present invention relates to an information processing apparatus required to ensure high performance and high reliability and, more particularly, to techniques of memory control in built-in type controller systems.

### BACKGROUND ART

Recent years have seen the advent in succession of high-speed memory devices operating in rapid burst transmission mode for fast access. Such memory devices include EDO mode DRAMs, synchronous DRAMs (SDRAM) and synchronous SRAMs. They perform pipeline processing that involves continuously switching addresses to read and output data successively in synchronism with a clock signal.

Meanwhile, recent advances in semiconductor technology have entailed widespread acceptance of microcomputers in diverse applications. Controllers to be incorporated into various kinds of equipment to assume their control functions are getting smaller in size and higher in performance thanks to built-in type microcomputers adopted by the controllers. Typical built-in type microcomputers include Hitachi's SH microcomputers (SH-2, SH-3). The SH microcomputer offers two interface functions: ordinary single access interface function (one data item accessed per bus cycle), and burst access interface function. Depending on the user system it is built into, the microcomputer allows one of the two interface functions to be selected. Specifically, the burst access interface capability is an interface that permits direct connection with the SDRAM without recourse to an externally added circuit. As such, the interface is suitable for making the microcomputer and the user system it is placed in smaller in size than ever.

A growing number of microcomputers are also finding their way into fields requiring enhanced reliability, such as health care, plant control, traffic control, and automotive control. A well-known factor posing a threat to the reliable operation of microcomputers is the incidence of memory data error attributable to the presence of noise and alpha rays. This potential problem is generally bypassed by use of a parity or ECC (error correcting code) function provided for the memory.

To implement the ECC function illustratively involves adding a 7-bit error correcting code to each 32-bit data item for 1-bit error correction and 2-bit error detection. The memory with the ECC function operates basically as follows: when a 32-bit data item is to be written to the memory, a 7-bit ECC is generated and added to the data item so that a combined 39-bit data item is written. The ECC-equipped 39-bit data item is subsequently retrieved from the memory and subjected to ECC error detection and correction before the 32-bit data item is acquired. What complicates the ECC control procedure is the need to generate an error correcting code (ECC bits) always with respect to a 32-bit data item. Whereas 32-bit data items are each written simply with the necessary ECC bits added thereto, an operation of writing a byte-long data item requires executing the following steps:

(a) Read 32-bit data from a target write address of the memory.

(b) Embed target write data into the data retrieved in step (a) above to create a new 32-bit data item.

(c) Generate ECC bits and write the data obtained in step (b) together with the ECC bits to the memory.

The writing of a byte-long data item is called a partial write, and the operation involved is called a read modify write.

Many built-in type microcomputers including the SH microcomputer are not equipped with the ECC function. Thus they need to be attached to an external ECC control circuit.

Two problems arise when an ECC control circuit is externally attached to a CPU having the burst access interface function such as that of the SH microcomputer:

The first problem is that when it is desired to use the burst access interface function for fast memory access, partial writes (byte-long write operations) cannot be performed with that function.

The second problem is that while it is possible to employ the single access interface function to carry out partial writes, the rapid burst transmission mode cannot be used with that function and thus fast memory access is unavailable.

In the description that follows, the terms “assert” and “negate” are used to avoid confusion between “active-high” signals and “active-low” signals. A signal name prefixed with a symbol “\mathring{0}” indicates that the signal is “active-low”. The term “asserted” means that the signal in question is active, i.e., it is “true” regardless of its electric potential level being High or Low. Conversely, the term “negated” signifies that the signal is inactive, i.e., it is “false.”

### DISCLOSURE OF INVENTION

It is therefore an object of the present invention to provide an information processing apparatus capable of permitting high-speed memory access while ensuring high reliability in operation based on the ECC scheme.

In carrying out the invention and according to one aspect thereof, there is provided an information processing apparatus comprising: a CPU having a first and a second data transfer interface, the first data transfer interface transferring data in a predetermined mode, the second data transfer interface transferring data in a mode different from that predetermined mode; a memory controller having first and second error detecting and controlling means corresponding to the first and the second data transfer interface respectively, the memory controller controlling data write and read operations between a memory and the CPU; and selecting means for assigning the first and the second error detecting and controlling means to different address spaces and for selecting one of the first and the second error detecting and controlling means in accordance with an address generated for access to the memory; wherein the memory is accessed by one of the first and the second error detecting and controlling means selected on the basis of an output from the selecting means.

Specifically, the first and the second data transfer interface are used to transfer data in burst access mode and single access mode, respectively. The first and the second error detecting and controlling means comprise an ECC control function each. In writing data of less than N bits, the second error detecting and controlling means first reads N-bit-wide data from the memory, embeds the target data of the less than N bits into the read-out N-bit-wide data, and adds an error correcting code to the read-out data embedded with the target data (i.e., to perform a partial write).

The inventive information processing apparatus of the constitution outlined above allows either the burst access interface or the single access interface to be selected as needed and ensures high reliability in operation based on the ECC control function. The high-speed burst access interface is used ordinarily and the single access interface is utilized only when necessary, whereby the average memory access speed is boosted. That is, the inventive apparatus offers both ECC-based high reliability and an enhanced memory access speed using the burst access interface.

### BRIEF DESCRIPTION OF DRAWINGS

FIG. 1 is a block diagram outlining a typical constitution of an embodiment of the invention;

FIG. 2 is a map showing address space assignments;

FIG. 3 is a block diagram illustrating how addresses are decoded;

FIG. 4 is another map showing address space assignments;

FIG. 5 is another block diagram indicating how addresses are decoded;

FIG. 6 is a block diagram depicting an internal constitution of an MCU;

FIG. 7 is a block diagram showing a simplified MCU internal constitution;

FIG. 8 is a wiring diagram sketching connections among a CPU, an MCU and SDRAMs;

FIG. 9 is a block diagram showing a data path structure inside the MCU;

FIG. 10 is a block diagram depicting a typical constitution of controllers inside the MCU;

FIG. 11 is a block diagram illustrating how latency is established;

FIG. 12 is a timing chart applicable to read operations in burst access mode;

FIG. 13 is a timing chart applicable to write operations in burst access mode;

FIG. 14 is a timing chart applicable to read operations in single access mode;

FIG. 15 is a timing chart applicable to 32-bit write operations in single access mode;

FIG. 16 is a timing chart applicable to partial write operations in single access mode;

FIG. 17 is a timing chart applicable to error address latch operations;

FIG. 18 is a block diagram of another embodiment of the invention;

FIG. 19 is a block diagram of a further embodiment of the invention;

FIG. 20 is a block diagram of an even further embodiment of the invention;

FIG. 21 is a block diagram showing a typical system configuration; and

FIG. 22 is a block diagram depicting typical system bus connections.

### BEST MODE FOR CARRYING OUT THE INVENTION

The best mode for carrying out the invention will now be described with reference to the accompanying drawings.

(First Embodiment)

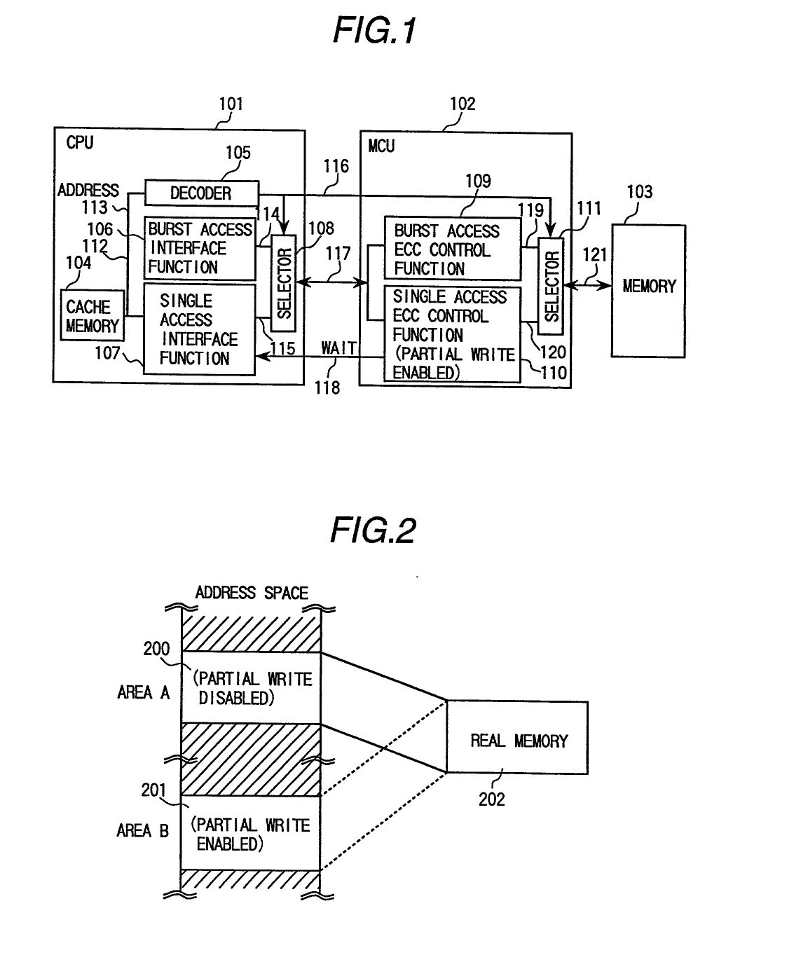

FIG. 1 is a block diagram outlining a typical constitution of a first embodiment of the invention. As illustrated, the first embodiment comprises a CPU (central processing unit, microcomputer) 101, an MCU (memory control unit) 102 and a memory 103.

The CPU 101 incorporates a cache memory 104. An operation for access to the external memory 103 is started (through an internal interface 112) in the absence of a copy in the cache memory (i.e., cache miss) upon an instruction fetch, or upon execution of an instruction for data transfer between an internal register of the CPU and memory. For access to the external memory 103, either a burst access interface function 106 or a single access interface function 107 is selected. The selection of the function is determined by a decoding circuit 105. The decoding circuit 105 identifies an address space in accordance with a partial address 113 of the internal interface 112. A selector 108 selects either an external memory input/output 114 of the burst access interface function 106 or an external memory input/output 115 of the single access interface function 107, depending on an output 116 of the decoding circuit 105. What is selected by the selector 108 is output from the CPU 101 (through an external input/output interface 117).

The MCU 102 is intended to support ECC (error correcting code) capabilities and is thus characteristic of this invention. The MCU 102 incorporates a burst access ECC control function 109 and a single access ECC control function 110. The burst access ECC control function 109 transfers 32-bit data continuously on a pipeline basis. The function 109 detects any error in, and generates an ECC to, each 32-bit-long data item. The single access ECC control function 110 reads and writes 32-bit-long data items, and writes 16- and 8-bit-long data items together with an ECC each (i.e., partial write). Selecting one of the two ECC control functions must be predicated on the internal arrangements of the CPU 101. For that reason, a selector 111 selects either an external memory input/output 119 of the burst access ECC control function 109 or an external memory input/output 120 of the single access ECC control function 110 depending on the output 116 of the decoding circuit 105. What is selected by the selector 111 is output from the MCU 102 (through an external memory interface 121). A \hat{0}WAIT output 118 is a cycle extension request signal supported for the single access ECC control function 110 only. This signal is used to implement a cycle extension required for a partial write operation.

The memory 103 supports a rapid burst transmission function. Illustratively, the memory 103 is composed of a DRAM or an SDRAM arrangement.

Functions of the decoding circuit 105 shown in FIG. 1 will now be described in detail. The decoding circuit 105 is intended to assign a burst access area (partial write disabled) and a single access area (partial write enabled) within address space.

FIG. 2 shows an example of address space assignments. In this example, a partial write disabled area A 200 and partial write enabled area B 201 are shown to be assigned to totally different space segments. Each area has the same size as that of a real memory area 202. Access to each area is effected physically within a single memory setup.

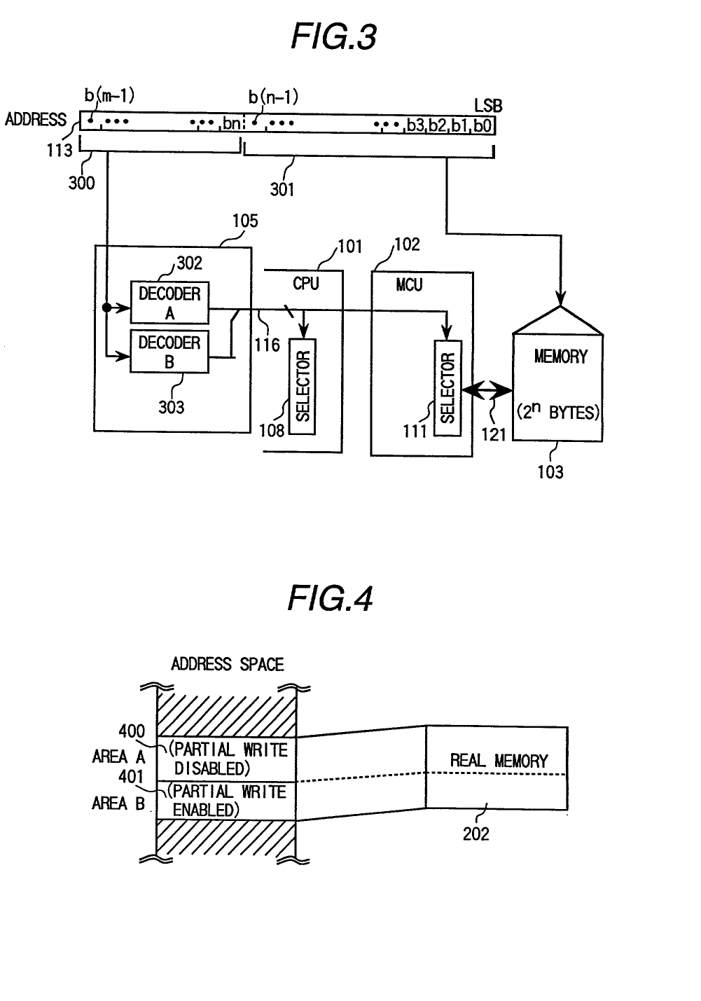

FIG. 3 depicts a setup comprising the decoding circuit 105 for implementing the address space assignments shown in FIG. 2. An address 113 is m bits long representing a byte address. The memory 103 is assumed to have a capacity of 2ⁿ bytes. On that assumption, a specific byte address in an area (e.g. the area 202 in FIG. 2) of the memory 103 is designated by bits 301 ranging from an LSB (least significant bit) b0 to a bit b(n−1). Bits 300 ranging from a bit bn to a bit b(m−1) designate the area A 200 or B 201 in address space. A decoder A 302 identifies the area A and a decoder B 303 identifies the area B.

For example, if the address 113 is 32 bits long and if the memory 103 has a capacity of 8 megabytes, then m=32 and n=23. The address space is divided into 128 8-megabyte address areas. Whereas one area is normally assigned the space of the memory 103, this embodiment allows a single memory to be accessed as an 8-megabyte address area from any one of the two areas A and B.

As a feature of this invention, the area A 200 is a burst access area (partial write disabled) and the area B 201 is a single access area (partial write enabled). A typical system gains access to one of the two areas selectively using a copy back type cache memory. That is, the area A 200 is an area where only burst access transfers are performed in increments of cache lines (e.g., in units of 16 bytes); the area B 201 serves as an area requiring 16- or 8-bit-long data write operations, with the cache memory turned off. Suitable software permits selective use of one of the two areas.

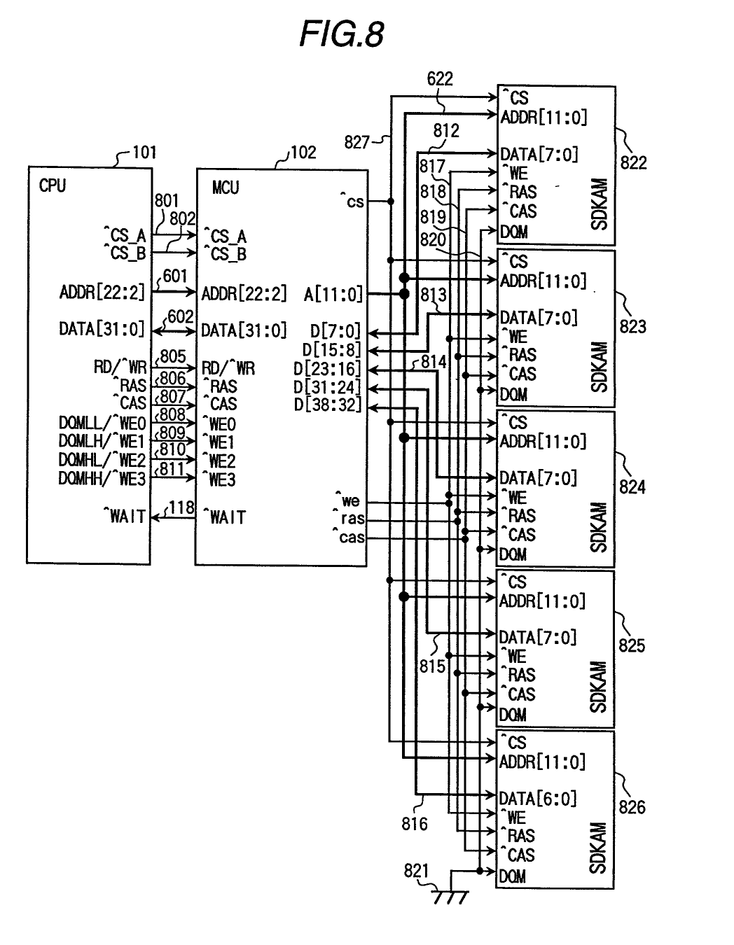

FIG. 8 depicts typical wiring connections among the CPU 101, the MCU 102, and SDRAMs constituting the memory 103 shown in FIG. 1. There are five SDRAMs each comprising 16 megabits (1,048,576 words×8 bits×2 banks). Of these SDRAMs, four memories (822 through 825) have each a capacity of 8 megabytes in increments of 32-bit data, and one memory (826) is assigned 7-bit ECC data. Each 32-bit data item is supplemented by a 7-bit ECC under the so-called SECDED (single bit error correction/double bit error detection) scheme. That is, the SECDED setup is capable of correcting 1-bit errors and detecting 2-bit errors.

Connection signals shown in FIG. 8 are outlined below.

(1) Interface Signals for the CPU 101 and MCU 102

A CPU signal named \hat{0}CS_A (No. 801) indicates the selection of burst access to the memory. This signal corresponds to the output 116 in FIG. 1. A CPU signal \hat{0}CS_B (No. 802) indicates the selection of single access to the memory; the signal also corresponds to the output 116 in FIG. 1. A CPU signal ADDR[22:2] (No. 601) represents an address output made of bits 22-2 (21 bits) designating a (2M×4) byte space. In burst access mode, a column address and a row address are output to [13:2] on a time division basis. A CPU signal DATA[31:0] (No. 602) represents a data input/output that is 32 bits long and 4 bytes wide. A CPU signal RD/\hat{0}WR (No. 805) indicates a read/write operation to or from the memory. A CPU signal \hat{0}RAS (No. 806) is a row address strobe signal that is used by the burst access interface. A CPU signal \hat{0}CAS (No. 807) is a column address strobe signal that is also used by the burst access interface. A CPU signal DQMLL/\hat{0}WEO (No. 808) represents a write mask for data [7:0]. A CPU signal DQMLH/\hat{0}WE1 (No. 809) denotes a write mask for data [15:8]. A CPU signal DQMHL/\hat{0}WE2 (No. 810) is a write mask for data [23:16]. A CPU signal DQMHH/\hat{0}WE3 (No. 811) is a write mask for data [31:24]. A CPU signal \hat{0}WAIT (No. 118) represents a wait signal input for requesting cycle extension in single access mode.

(2) Interface Signals for the MCU 102 and SDRAMs (822 Through 826)

An MCU signal named \hat{0}cs (No. 827) is a chip select signal which, only when asserted, enables other control signals of the SDRAM in question. An MCU signal A[11:0] (No. 622) denotes an address output. An MCU signal D[7:0] (No. 812) represents byte 0 of a data input/output. An MCU signal D[15:8] (No. 813) denotes byte 1 of the data input/output. An MCU signal D[23:16] (NO. 814) indicates byte 2 of the data input/output. An MCU signal D[31:24] (No. 815) designates byte 3 of the data input/output. An MCU signal D[38:32] (No. 816) represents an ECC data input/output. An MCU signal \hat{0}WE (No. 817) is a write enable signal. An MCU signal \hat{0}RAS (No. 818) is a row address strobe signal. An MCU signal \hat{0}CAS (No. 819) is a column address strobe signal.

(3) Others

An SDRAM signal named DQM (No. 820) denotes a data input/output mask. This signal is not used by this embodiment (no mask provided), and is connected fixedly to a ground 821.

The following points should be noted for this invention:

(A) The signals \hat{0}CS_A (801) and \hat{0}CS_{—B} (802) are used to select burst access or single access to the memory.

(B) The signal ADDR (601) functions differently in burst access mode and in single access mode.

(C) The signals \hat{0}RAS (806) and \hat{0}CAS (807) are used in burst access mode only.

(D) The signal \hat{0}WAIT (118) is used in single access mode only.

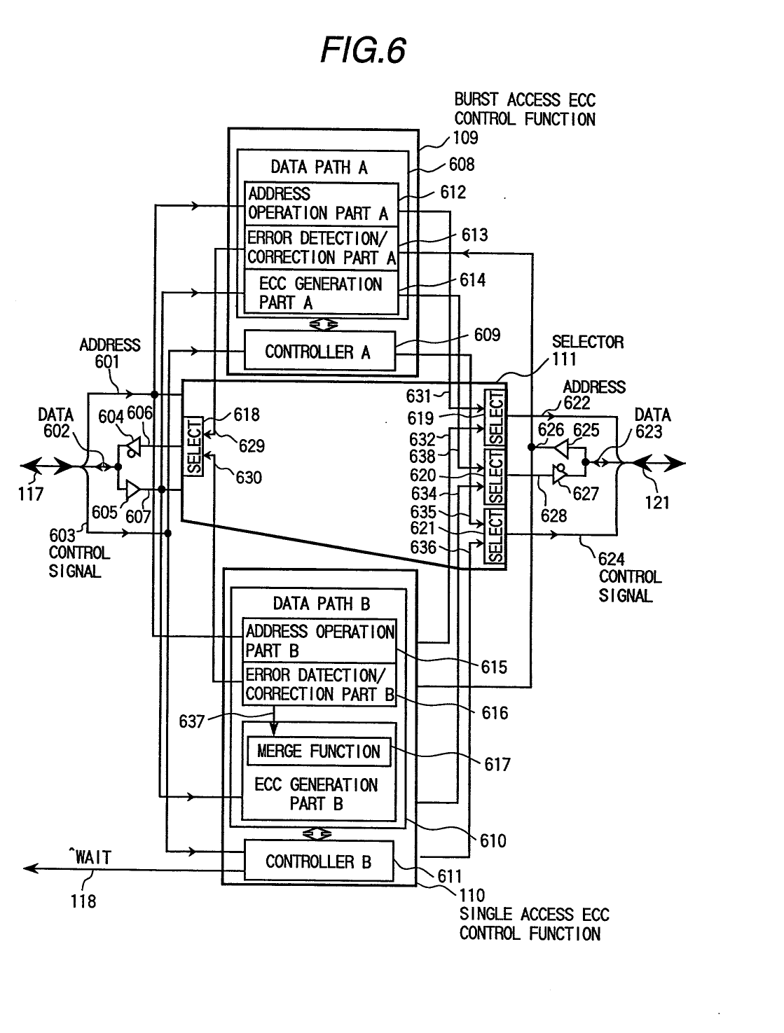

The MCU 102 will now be described in detail by referring to the signals outlined above. FIG. 6 depicts an internal constitution of the MCU 102. The burst access ECC control function 109 includes two major components: a data path A 608 and a controller A 609. The data path A 608 incorporates an address operation part A 612, an error detection/correction part A 613, and an ECC generation part A 614. The address operation part A 612 admits an address 601, operates on it and provides an output 631. In a read operation, the error detection/correction part A 613 admits data 626, detects and corrects any error in the data using ECC, and yields an output 629. In a write operation, the ECC generation part A 614 admits data 607, generates ECC bits, and gives a data-ECC-combination output 638.

Meanwhile, the single access ECC control function 110 comprises two major components: a data path B 610 and a controller B 611. The data path B 610 incorporates an address operation part B 615, an error detection/correction part B 616, and an ECC generation part B 617. The address operation part B 615 admits an address 601, operates on it and provides an output 632. In a read operation, the error detection/correction part B 616 admits data 626, detects and corrects any error in the data using ECC, and yields an output 630. In a write operation, the ECC generation part B 617 admits data 607, generates ECC bits, and gives a data-ECC-combination output 634.

When the error detection/correction part B 616 provides the output 630, the same data is output simultaneously to the ECC generation part B 617. The data output 637 constitutes a data path for merging the write data 607 with data that was read from the memory for a partial write operation.

The selector 111 includes selecting functions 618 through 621 for outputting addresses, reading and writing data, and selecting control signals. More specifically, the selecting function 619 selects address outputs 631 and 632. The selecting function 618 selects data 629 and 630 for data read operations. The selecting function 620 selects data 633 and 634 for data write operations. The selecting function 621 selects control signals 635 and 636.

The external input/output interface 117 exchanged with the CPU 101 has the address 601, data 602, and a control signal 603. The interface signal 121 exchanged with the memory comprises an address 622, data 623, and a control signal 624.

Because the data 601 and 623 being read or written by the CPU 101 have different input/output directions, they are transmitted in a selective manner to the two ECC control functions 109 and 110 or to the selecting functions in the selector 111. For data read operations, a buffer 625, a buffer output 626, a selector output 606 and a buffer 604 are used; for data write operations, a buffer 605, a buffer output 607, a selector output 628 and a buffer 627 are used.

The constitution of FIG. 6 comprises arrangements that directly reflect the basic concept of this invention. Simplifying these arrangements reduces hardware cost when the invention is implemented. For example, the error detection/correction part B 616 may double functionally as the error detection/correction part A 613. The ECC generation part B 617 differs from the ECC generation part A 614 only in terms of a merge function being present or absent. As such, the two generation parts 617 and 614 may be replaced by a single part, with the redundant output selector omitted.

FIG. 7 depicts a simplified MCU internal constitution based on the setup of FIG. 6, with a smaller number of components in FIG. 7 taking over the greater number of functions in FIG. 6. More specifically, the setup of FIG. 7 comprises an error detection/correction part AB 701 and an ECC generation part AB 702 each serving as a double-function part. Selectors corresponding to outputs 704 and 705 of these parts are unnecessary and are thus omitted. The ECC generation part AB 702 has the merge function capable of merging write data 607 with data 703 output by the error detection/correction part AB 701. The merge function is used only for partial write operations under the direction of the controller B.

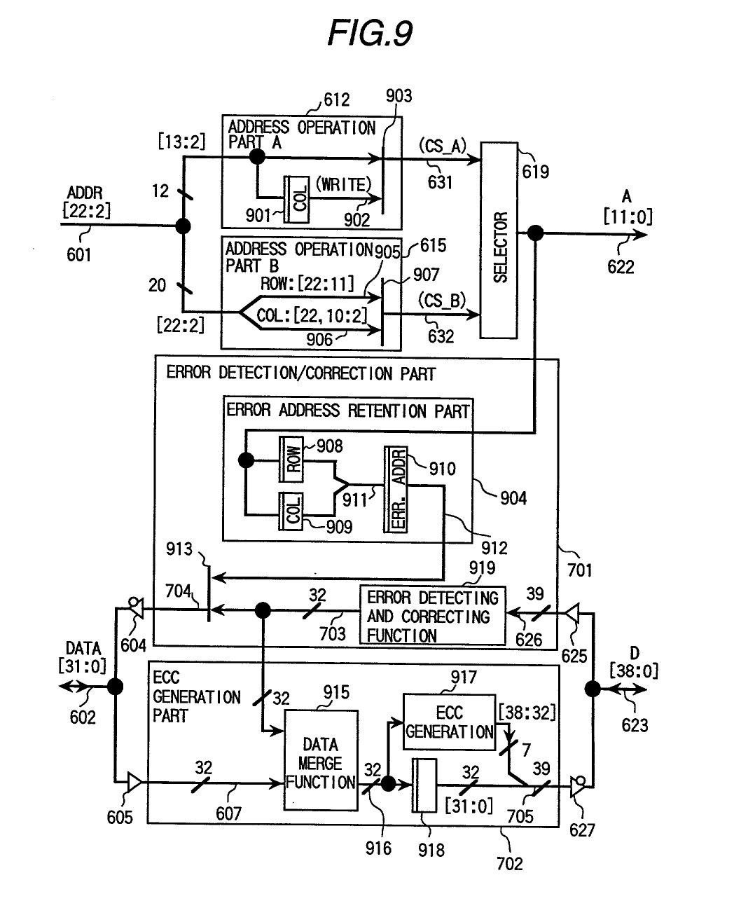

A modified embodiment based on the constitution of FIG. 7 will now be described in more detail. FIG. 9 illustrates a data path structure inside the MCU. The structure details the data path 706 in FIG. 7, and it is shown in relation to the connections in FIG. 8.

The address operation part A 612 is intended to operate on addresses in burst access mode. One capability required of the address operation part A 612 is to delay by one cycle the point in time at which a column address is fed to the SDRAM for ECC generation in a write operation (to be described later). Thus when a column address for the write operation is to be fed to the SDRAM, an output 902 of a column address latch 901 is selected (by selector 903); otherwise ADDR[13:2] nis output unmodified (631). The output 631 remains effective when the signal \hat{0}CS_A (801) shown in FIG. 8 is asserted by the selector 619.

The address operation part B 615 is intended to operate on addresses in single access mode. In single access mode, the address operation part B 615 selects a row address (corresponding to ADDR[22:11]) and a column address (corresponding to ADDR[22] and ADDR[10:2]; ADDR[22] involves selection of a bank) and supplies the selected addresses to the SDRAM (905, 906, 907, 632). The output 632 remains effective when the signal \hat{0}CS_B (802) shown in FIG. 8 is asserted by the selector 619.

The error detection/correction part AB 701 includes an error detecting and correcting function 919 and an error address retention part 904. The error detecting and correcting function 919 detects and corrects any error in read-out data under the SECDED scheme. In both burst access mode and single access mode, the read-out data is transferred to the CPU 101 through the error detecting and correcting function 919.

The error address retention part 904 is intended to retain the address of any error that may be detected in the read-out data, so that the error address may be read later by the CPU 101. When a data error is detected, the CPU 101 may be notified thereof by an interruption or by a flag being set in a specific register.

The error address retention part 904 contains a row address latch 908, a column address latch 909, and an error address latch 910 that admits a combined output 911 of the other two latches. When addresses are reconstituted from the output of the selector 619, they may be used commonly in burst access mode and in single access mode. A selector 913 selects an output 912 of the error address latch 910 only at the time of an error address read operation and outputs what is selected (output 704). Otherwise the selector 913 selectively outputs the data 703 that is output by the error detecting and correcting function 919.

The ECC generation part AB 702 has a merge function 915 for merging write data 607 with the data 703 output by the error detection/correction part AB 701. The merge function is utilized only for partial write operations under the direction of the controller B. When a partial write operation takes place, the controller B read 32-bit data from the address to write to of the memory. The write data 607 for the partial write operation is embedded into the read-out data 703, and the result is output (916). Where partial write operations are not carried out, the merge function simply lets the input 607 be output unmodified (916).

An ECC generation part 917 is capable of generating seven ECC bits for each 32-bit data item 916. A temporary latch 918 is provided to retain the data for one cycle in keeping with a delay time in which the ECC generation part 917 generates the ECC bits.

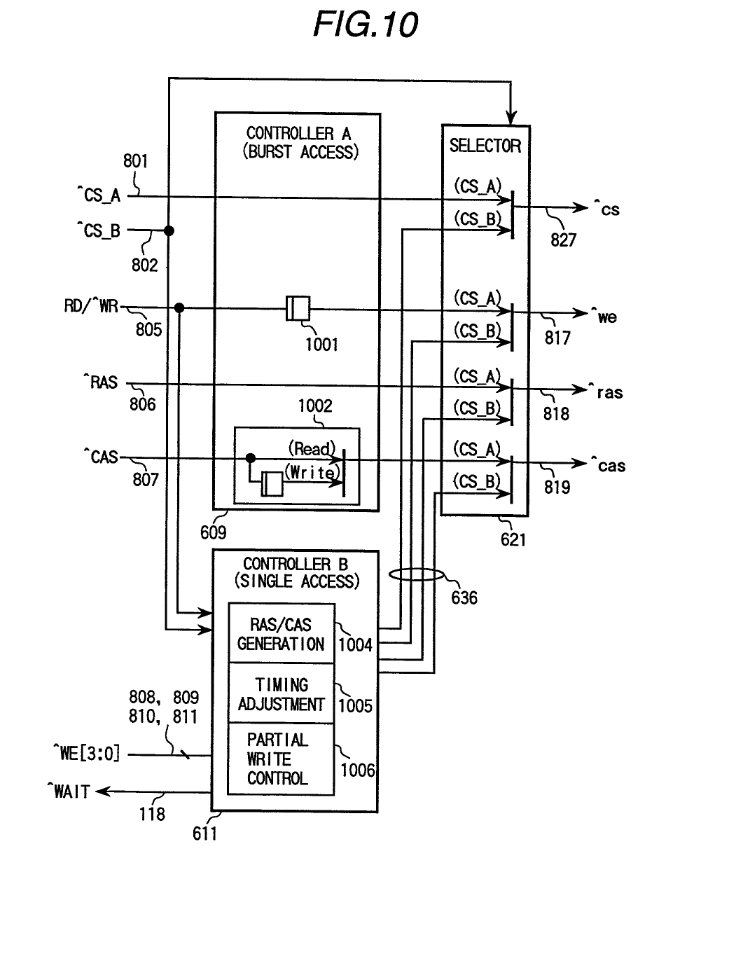

FIG. 10 is a block diagram depicting a typical constitution of controllers inside the MCU. The constitution details peripheral portions of the controllers A 609 and B 611 in FIG. 7, and these portions are shown in relation to the connections in FIG. 8.

The controller A 609 controls burst access mode. The controller A 609 basically lets burst access control signals from the CPU 101 be output unmodified, except when a column address and write data are output for a write operation. In that exceptional case, it is necessary to delay the column address and write data by one cycle in keeping with the delay time in which to generate the ECC bits. Two latches 1001 and 1002 are provided for the purpose.

The controller B 611 controls single access mode. In single access mode, the CPU 101 does not output the signals \hat{0}RAS (806) and \hat{0}CAS (807) for direct SDRAM control. This means that the controller B 611 must generate these signals in single access mode (RAS/CAS generation 1004). It is also necessary to adjust various control timings (1005) and to effect partial write control (1006) in single access mode.

The selector 621 selects the output of control signals from the controllers A 609 and B 611. With this embodiment, the selector 621 selects the control signal output from the controller B 611 only when the signal \hat{0}CS_B (802) is asserted; the selector 621 selects the control signal output from the controller A 609 when the signal \hat{0}CS_B (802) is negated.

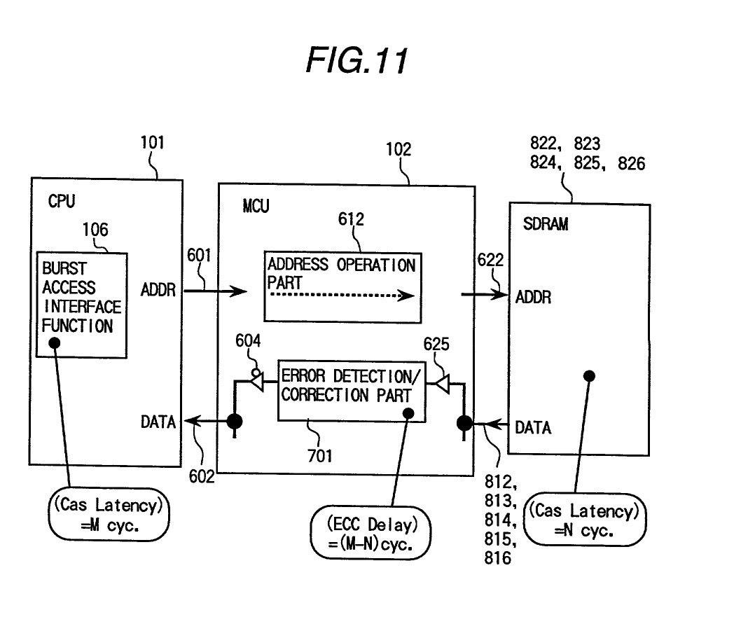

How SDRAM operation settings are typically made will now be described by referring to FIG. 11. For read operations, each of the SDRAMs (822 through 826) may have what is known as Cas Latency set in an internal register (for N-cycle count). The Cas Latency designates the number of cycles that elapse from the time a column address is fed to the address 622 until a data output (812 through 816) is effected. The CPU 101 has a similar register in its burst access interface function 106. When an appropriate value is set in this register, the CPU 101 receives desired data 602 in a suitably timed fashion. If the MCU 102 is not interposed between the CPU 101 and the SDRAM, i.e., if the CPU 101 directly controls the SDRAM, then the Cas Latency on the side of the burst access interface function 106 is the same as that of the SDRAM. With this invention, however, the MCU 102 is placed interposingly between the CPU 101 and the SDRAM. To secure a sufficient delay time for the error detection/correction part 701 in this arrangement requires that the burst access interface function 106 be given a Cas Latency setting of M cycles, greater than the N cycles for the SDRAM. This makes it possible to ensure (M−N) cycles of delay time for the error detection/correction part 701.

In this embodiment, the values M and N are set for 3 and 2 cycles respectively. Thus the delay time (M−N) secured for the error detection/correction part 701 is one cycle.

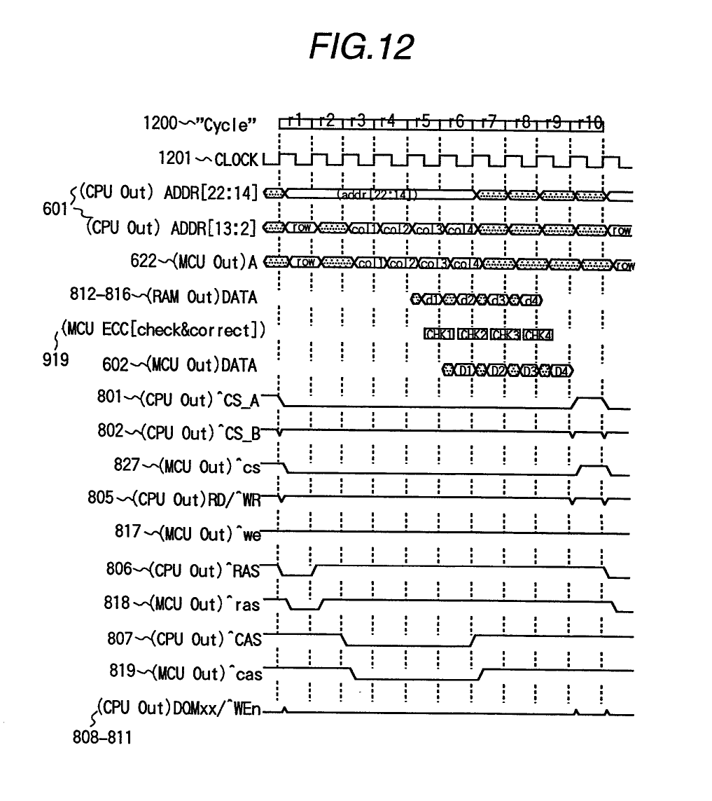

Below is a description of how the arrangements of FIGS. 8, 9 and 10 operate, with reference to timing charts in FIGS. 12 through 17. In the description that follows, the above explanation of the Cas Latency will be referred to and taken into account.

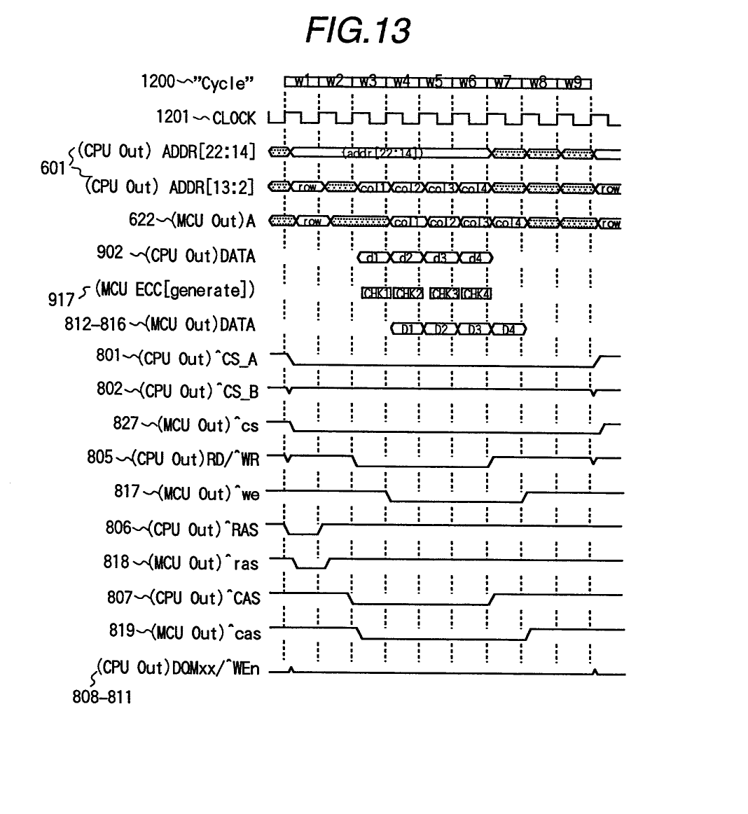

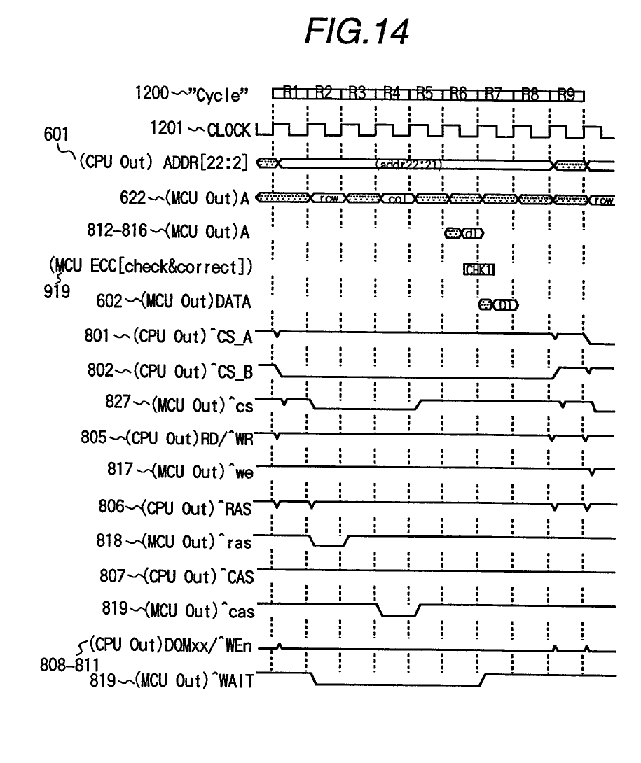

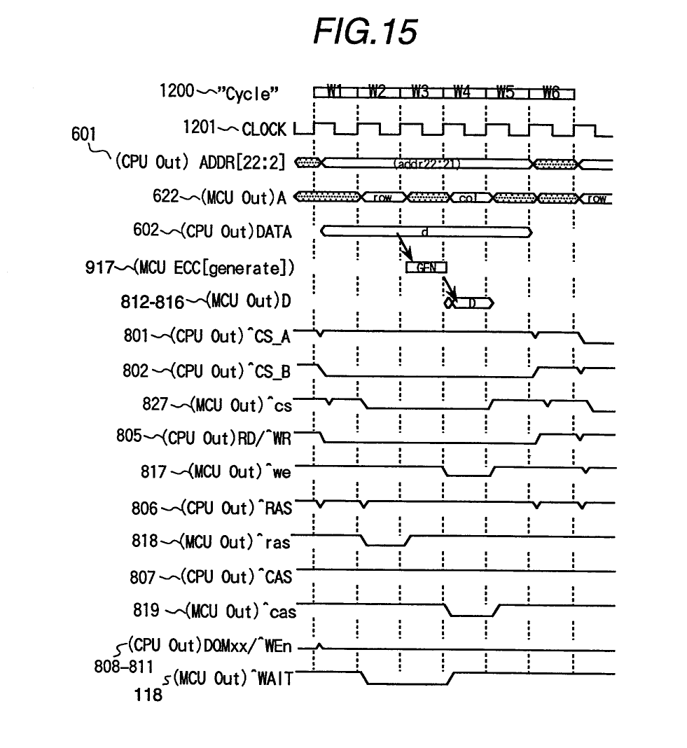

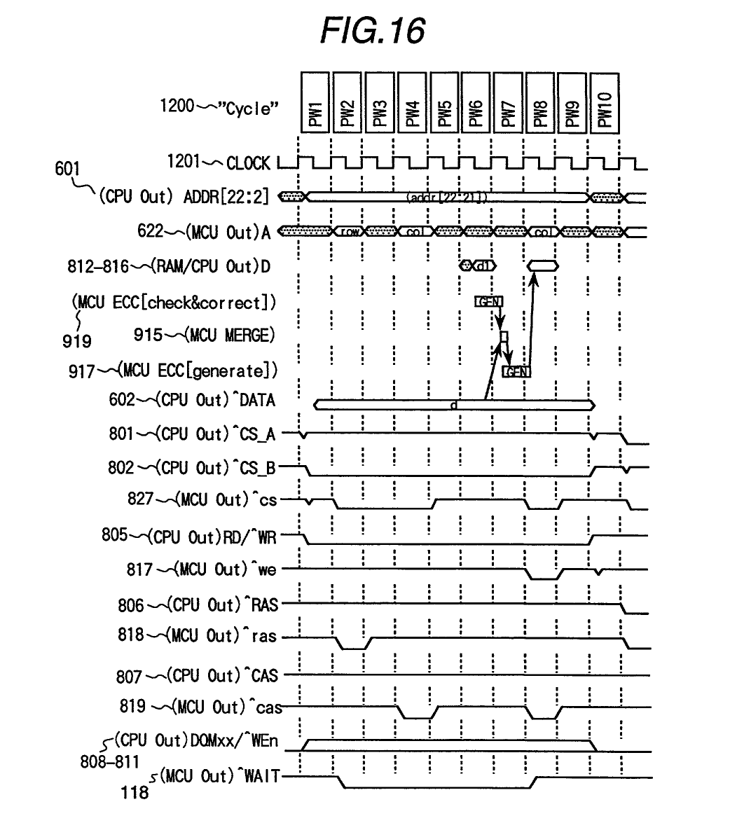

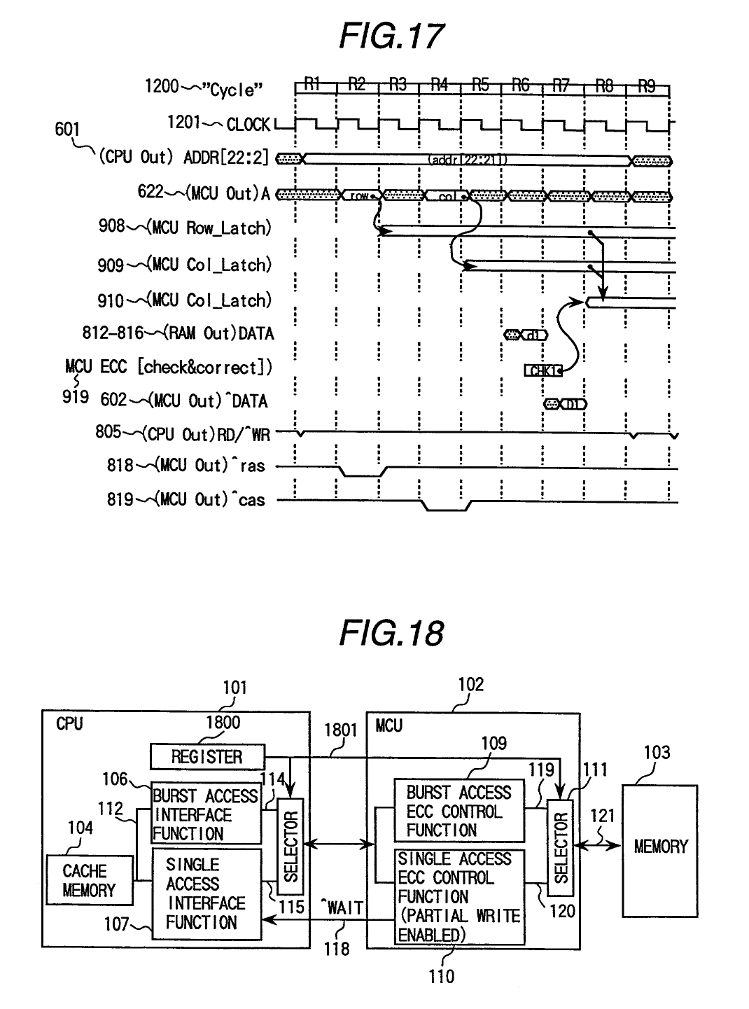

FIG. 12 is a timing chart applicable to read operations in burst access mode. FIG. 13 is a timing chart applicable to write operations in burst access mode. FIG. 14 is a timing chart applicable to read operations in single access mode. FIG. 15 is a timing chart applicable to 32-bit write operations in single access mode. FIG. 16 is a timing chart applicable to partial write operations in single access mode. FIG. 17 is a timing chart in effect when the error address retention part 904 shown in FIG. 9 is in operation.

In each of the above-cited timing charts, an indication “Cycle” (1200) is given at the top of the chart to denote cycle names. For purpose of explanation, each time unit representing one bus cycle is given a name and identified thereby. Below the “Cycle” in each chart is “CLOCK” (1201) indicating a waveform of a common clock signal fed to the CPU 101, MCU 102 and SDRAMs (822 through 826). Others that come under the “CLOCK” are waveforms of the connection signals shown in FIG. 8 and operation timings of the functions depicted in FIG. 9.

FIG. 12 is a timing chart in effect when a memory read operation takes place in burst access mode. The CPU 101 reads data four times in a single burst data transfer. In updating addresses, the CPU 101 of this embodiment designates each of the four column addresses.

In burst access mode, the CPU 101 outputs row and column address values so that the SDRAM is connected directly to a low-order part [13:2] of the address 601. As illustrated, the row address appears in cycle r1, and the four column addresses appear in succession in cycles r3 through r6. Upon receipt of these addresses, the MCU 102 allows them to be output to the SDRAM without operating thereon (622, r1 through r6). Inside the MCU 102, the address operation part A 612 is used selectively to effect the address output.

The read-out data from the SDRAM appears in cycles r5 through r8 (812 through 816). These cycles correspond to the column addresses issued in cycles r3 through r6. The cycle delay is provided in accordance with the value “2” set earlier for Cas Latency.

On receiving the read-out data, the MCU 102 causes the error detecting and correcting function 919 inside to detect any error in the data. If a 1-bit error is detected, the function 919 corrects the error (in cycles r5 through r9).

Eventually, the MCU 102 outputs the data 602 to the CPU 101 in cycles r6 through r9. In accordance with the value “3” set earlier for Cas Latency, the CPU 101 observes the cycle delay when receiving the data.

The control signals shown in FIG. 12 are described below. When the signal \hat{0}CS_A (801) is asserted, the MCU 102 recognizes the start of burst access cycles. While the signal \hat{0}CS_A (801) is being asserted, the signal \hat{0}CS_B (802) is not asserted. Inside the MCU 102, the controller A 609 is used selectively to output the suitable control signals.

The signal \hat{0}CS (827) to the SDRAM is kept asserted during the bus cycles. Because the output RD/\hat{0}WR (805) of the CPU 101 denotes a read operation when brought High, the signal \hat{0}we (817) to the SDRAM also remains High. The signals \hat{0}RAS (806) and \hat{0}CAS (807) generated by the CPU 101 are output unmodified to the SDRAM (818, 819) at the time of a read operation. During read operations, the signals DQMxx/\hat{0}WEn (808 through 811) are all held Low.

FIG. 13 is a timing chart in effect when a memory write operation takes place in burst access mode. The CPU 101 writes data four times in a single burst data transfer. In updating addresses, the CPU 101 of this embodiment designates each of the four column addresses.

In burst access mode, the CPU 101 outputs row and column address values so that the SDRAM can be connected directly to a low-order part of the address 601. As illustrated, the row address appears in cycle w1, and the four column addresses appear successively in cycles w3 through w6. Upon receipt of these addresses, the MCU 102 allows for a delay of one cycle for ECC generation, outputting the column addresses to the SDRAM one cycle later (622, w4 through w7). Inside the MCU 102, the signal side 902 of the selector 903 in the address operation part A 612 is selected.

The write data 602 to the SDRAM appears in cycles w3 through w6. These cycles correspond likewise to the column addresses issued in cycles w3 through w6.

The MCU 102 receives the write data. Inside the MCU 102, the ECC generation part 917 generates the necessary ECC bits. Eventually, the MCU 102 outputs the data together with the ECC bits to the SDRAM one cycle later, between cycles w4 and w7 (812 through 816).

The control signals included in FIG. 13 are described below. When the signal \hat{0}CS_A (801) is asserted, the MCU 102 recognizes the start of burst access cycles. While the signal \hat{0}CS_A (801) is being asserted, the signal \hat{0}CS_B (802) is not asserted. Inside the MCU 102, the controller A 609 is used selectively to output the suitable control signals.

The signal \hat{0}CS (827) to the SDRAM is kept asserted during bus cycles. Because the output RD/\hat{0}WR (805) of the CPU 101 denotes a write operation when driven Low, the signal \hat{0}we (817) to the SDRAM is also driven Low and is output one cycle later in synchronism with the data (812 through 816).

The signal \hat{0}RAS (806) generated by the CPU 101 is output (\hat{0}ras 818) unmodified to the SDRAM in the same manner as in a read operation. The signal \hat{0}CAS (807) is brought Low and is output (\hat{0}cas 819) one cycle later in keeping with the data (812 through 816). During write operations in burst access mode, the signals DQMxx/\hat{0}WEn (808 through 811) are all held Low.

FIG. 14 is a timing chart in effect when a memory read operation takes place in single access mode. The CPU 101 reads data only once in a single access data transfer.

In single access mode, the address 601 from the CPU 101 is simply output unmodified to bits [22:2]. Given the address, the MCU 102 operates on it so as to acquire a row and a column address to be supplied to the SDRAM. The row address is output in cycle R2 and the column address is output in cycle R4 to the SDRAM successively (622). The address output is accomplished by selectively using the address operation part B 615 inside the MCU 102.

The read-out data from the SDRAM appears in cycle R6 (812 through 816). The cycle corresponds to the column address issued in cycle R4. A cycle delay is provided in accordance with the Cas Latency setting mentioned earlier.

When the MCU 102 receives the read-out data, the error detecting and correcting function 919 inside detects any error that may be included in the data. If an error is detected, the function 919 corrects the error (in cycles R6 and R7). Eventually, the MCU 102 outputs the data (602) to the CPU 101 in cycle R7.

The control signals included in FIG. 14 are described below. When the signal \hat{0}CS_B (802) is asserted, the MCU 102 recognizes the start of single access cycles. Inside the MCU 102, the controller B 611 is used selectively to output the appropriate control signals.

The signal \hat{0}CS (827) to the SDRAM is asserted in cycles R2 through R4 in keeping with the signals \hat{0}ras (818) and \hat{0}cas (819). Because the output RD/\hat{0}WR (805) of the CPU 101 denotes a read operation when brought High, the signal \hat{0}we (817) to the SDRAM is also held High. Since the CPU 101 does not output the signals \hat{0}RAS (806) and \hat{0}CAS (807), the controller B 611 in the MCU 102 generates the signals \hat{0}ras (818) and \hat{0}cas (819) (in cycles R2 and R4). During read operations, the signals DQMxx/\hat{0}WEn (808 through 811) are all held Low.

The signal \hat{0}WAIT (118) is sampled by the CPU 101 starting from a leading edge of cycle R3. The MCU 102 asserts the signal \hat{0}WAIT between cycles R2 and R6.

FIG. 15 is a timing chart in effect when a 32-bit data item is written to the memory in single access mode. The CPU 101 writes data only once in a single access data transfer.

In single access mode, the address 601 from the CPU 101 is simply output unmodified to bits [22:2]. Given the address, the MCU 102 operates on it so as to acquire a row and a column address to be supplied to the SDRAM. The row address is output in cycle W2 and the column address is output in cycle W4 to the SDRAM in succession (622). The address output is accomplished by selectively using the address operation part B 615 inside the MCU 102.

The write data 602 from the CPU 101 is output in the same manner as the address 601. The MCU 102 receives the write data 602. Inside the MCU 102, the ECC generation part 917 generates the necessary ECC bits. Eventually, the MCU 102 outputs the data together with the ECC bits to the SDRAM in cycle W4 (812 through 816).

The control signals included in FIG. 15 are described below. When the signal \hat{0}CS_B (802) is asserted, the MCU 102 recognizes the start of single access cycles. Inside the MCU 102, the controller B 611 is used selectively to output the suitable control signals.

The signal \hat{0}CS (827) to the SDRAM is asserted in cycles W2 through W4 in keeping with the signals \hat{0}ras (818) and \hat{0}cas (819). Because the output RD/\hat{0}WR (805) of the CPU 101 denotes a write operation when driven Low, the signal \hat{0}we (817) to the SDRAM is also brought Low in cycle W4 in accordance with the signal \hat{0}cas. Since the CPU 101 does not output the signals \hat{0}RAS (806) and \hat{0}CAS (807), the controller B 611 in the MCU 102 generates the signals \hat{0}ras (818) and \hat{0}cas (819) (in cycles R2 and R4). During 32-bit data write operations, the signals DQMxx/\hat{0}WEn (808 through 811) are all held Low.

The signal \hat{0}WAIT (118) is sampled by the CPU 101 starting from a leading edge of cycle W3. The MCU 102 asserts the signal \hat{0}WAIT between cycles W2 and W3.

FIG. 16 is a timing chart in effect when a partial write operation to the memory takes place in single access mode. To execute a partial write operation requires carrying out the following steps because ECC bits are to be attached to each 32-bit data item:

(a) Read 32-bit data from the target address to which to write data (for ECC check).

(b) Embed the write data into the data obtained in step (a) to create new 32-bit data.

(c) Generate ECC bits with respect to the data acquired in step (b) before writing the data together with the ECC bits to the memory.

More specifically, the following takes place: in single access node, the address 601 from the CPU 101 is simply output unmodified to bits [22:2]. Given the address, the MCU 102 operates on it so as to acquire a row and a column address to be supplied to the SDRAM. In preparation for step (a), the row address is output in cycle PW2 and the column address is output in cycle PW4 to the SDRAM in succession. Preparatory to step (c), the column address is output to the SDRAM in cycle PW8 (622). The address output above is accomplished by selectively using the address operation part B 615 inside the MCU 102.

The read-out data from the SDRAM appears in cycle PW6 (812 through 816). The cycle corresponds to the column address issued in cycle PW4. A cycle delay is provided in accordance with the Cas Latency setting mentioned earlier.

When the MCU 102 receives the read-out data, the error detecting and correcting function 919 inside detects any error that may be included in the data. If an error is detected, the function 919 corrects the error (in cycles PW6 and PW7; step (a)).

The write data 602 is output in the same manner as the address 601. In cycle PW7, the data from the error detecting and correcting function 919 is merged with the write data 602 from the CPU 101 (917; step (b)). For the merged data, the ECC generation part 917 generates ECC bits. Eventually, the MCU 102 outputs the data together with the ECC bits in cycle PW8 to the SDRAM (812 through 816). The byte location where the merge is to occur is judged by use of the signals DQMxx/\hat{0}WEn (808 through 811).

The control signals included in FIG. 16 are described below. When the signal \hat{0}CS_B (802) is asserted, the MCU 102 recognizes the start of single access cycles. Inside the MCU 102, the controller B 611 is used selectively to output the suitable control signals.

The signal \hat{0}CS (827) to the SDRAM is asserted in cycles PW2 through PW4 and PW8 in keeping with the signals \hat{0}ras (818) and \hat{0}cas (819). Because the output RD/\hat{0}WR (805) of the CPU 101 denotes a write operation when driven Low, the signal \hat{0}we (817) to the SDRAM is also brought Low in cycle PW8 in accordance with the signal \hat{0}cas. Since the CPU 101 does not output the signals \hat{0}RAS (806) and \hat{0}CAS (807), the controller B 611 in the MCU 102 generates the signals \hat{0}ras (818) and \hat{0}cas (819) (in cycles PW2, PW4 and PW8).

In a partial write operation, the signals DQMxx/\hat{0}WEn (808 through 811) designate the byte location to write data to. If at least one of these signals is driven High, the controller B 611 recognizes the start of partial write cycles.

The signal \hat{0}WAIT (118) is sampled by the CPU 101 starting from a leading edge of cycle PW3. The MCU 102 asserts the signal \hat{0}WAIT between cycles PW2 and PW7. A comparison between FIGS. 15 and 16 reveals a difference in the number of execution cycles therebetween. With that difference taken into account, the assert time of the signal \hat{0}WAIT is varied so as to guarantee the normal operation for the CPU 101.

FIG. 17 is a timing chart in effect when the error address retention part 904 shown in FIG. 9 is in operation, wherein an error is detected while data is being read from the memory in single access mode.

During a memory read operation in single access mode, a row address is output in cycle R2 and a column address is output in cycle R4 to the SDRAM successively (622). The addresses are latched consecutively by the error address retention part 904 (by the row address latch 908 and column address latch 909).

Between cycles R6 and R7, the error detecting and correcting function 919 checks for error. If an error is detected, the two latched values (908 and 909) are placed into the error address latch (910) in cycle R8.

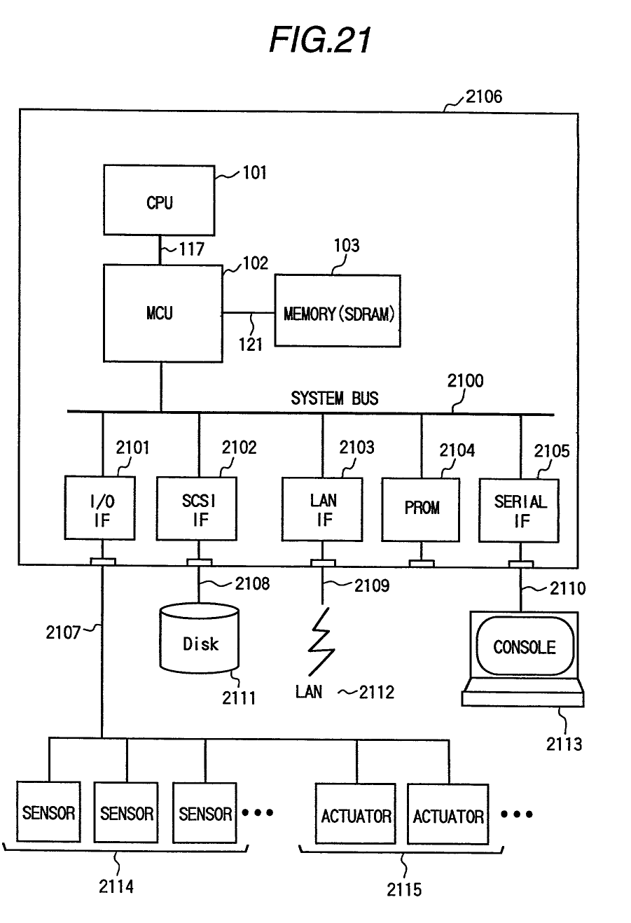

FIG. 21 is a block diagram showing a typical configuration of a system to which this invention is applied. In FIG. 21, a module 2106 has the following components: the CPU 101, the MCU 102 and the memory (SDRAM) 103 are the same as those described above. The other components, interconnected by a system bus 2100, include: an I/O interface 2101 for exchanging information through a connector 2107 with sensors 2114 and actuators 2115 for device control; a SCSI interface 2102 connected through a connector 2108 to a hard disk drive 2111 for exchanging information therewith; a LAN interface 2103 connected through a connector 2109 to a local area network 2112 for exchanging information with other core modules; a PROM (programmable read only memory) 2104 containing a boot program; and a serial interface 2105 connected serially to a console 2113 to provide interface with a user.

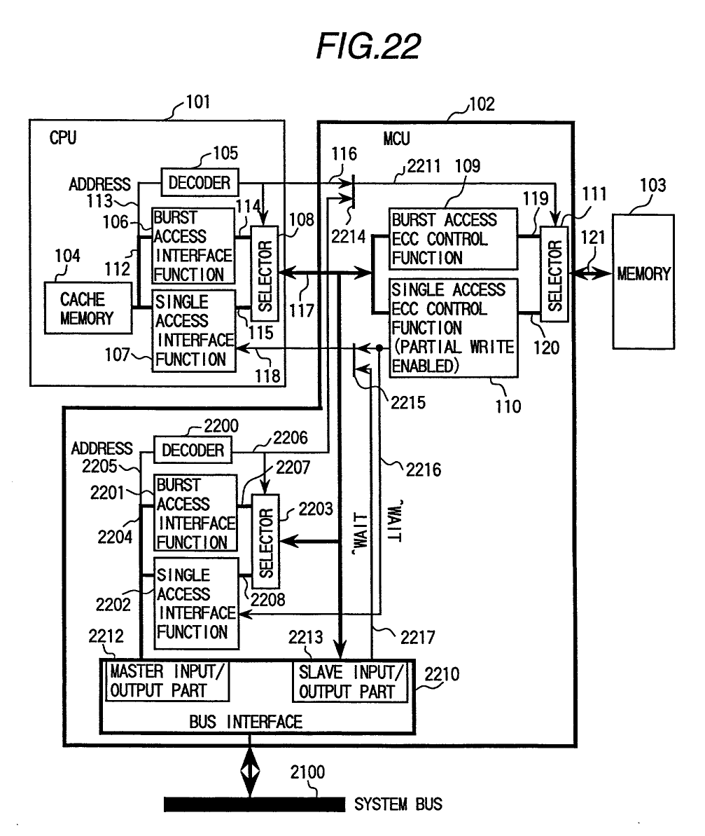

FIG. 22 is a block diagram depicting how the MCU 102 is typically connected to the system bus 2100 in the system configuration shown in FIG. 21. In the setup of FIG. 22, the following three types of access are available:

(A) The CPU 101 accesses the memory 103 through the MCU 102.

(B) The CPU 101 accesses a device on the system bus through the MCU 102.

(C) A device on the system bus accesses the memory 103 through the MCU 102.

The access of type (A) above has already been discussed. In the setup of FIG. 22, a selector 2214 is added. Upon type (A) access, the selector 2214 selects the output 116 of the decoding circuit 105.

The access of type (B) above is described below. The external input/output interface 117 of the CPU 101 is used not only for access to the memory but also for gaining access to a device on the system bus. The external input/output interface 117 is connected to a slave input/output part 2213 of a bus interface 2210. The data path thus formed permits access to a device attached to the system bus.

Access from the CPU 101 involves the use of the single access interface function 107. A signal \hat{0}WAIT (2217) from the slave input/output part 2213 is transmitted to the single access interface function 107 through a selector 2215. This arrangement provides for differences in data transfer rate between the CPU 101 on the one hand and different devices on the system bus on the other hand.

The access of type (C) above is described below. A device on the system bus may gain access to the memory 103 through a master input/output part 2212 of the bus interface 2210. The master input/output part 2212 accesses the memory 103 in the same manner as the CPU 101 gaining access to the same memory.

A request from a device on the system bus initiates access from the bus interface 2210 to the memory 103 (through interface 2204). For access to the memory 103, either a burst access interface function 2201 or a single access interface function 2202 is selected. A decoding circuit 2200 provides a basis for selecting one of the two functions. More specifically, the decoding circuit 2200 identifies an address space in effect in accordance with part of an address 2205 of the interface 2204. A selector 2203 selects either an input/output 2207 of the burst access interface function 2201 or an input/output 2208 of the single access interface function 2202, depending on an output 2206 from the decoding circuit 2200. The input/output thus selected is connected to the input/output interface 117 of the CPU 101. A signal \hat{0}WAIT (2216) is a cycle extension request signal supported for the single access interface function 107 only.

In the manner described above, any device on the system bus may gain access to the memory 103 either in burst access mode or in single access mode which may be selected as needed.

As described, the ECC-based measures for boosting the reliability enhances the average memory access speed through the selective use of burst or single access mode. The burst access interface is used normally for high speed data transfer; the single access interface is utilized only when necessary.

(Second Embodiment)

FIG. 4 is another map showing address space assignments. This map indicates that a partial write disabled area A 400 and a partial write enabled area B 401 are assigned to different but adjacent space segments. The two areas when combined are large enough to be accommodated precisely by the real memory area 202. Access to each area is effected physically within a single memory setup.

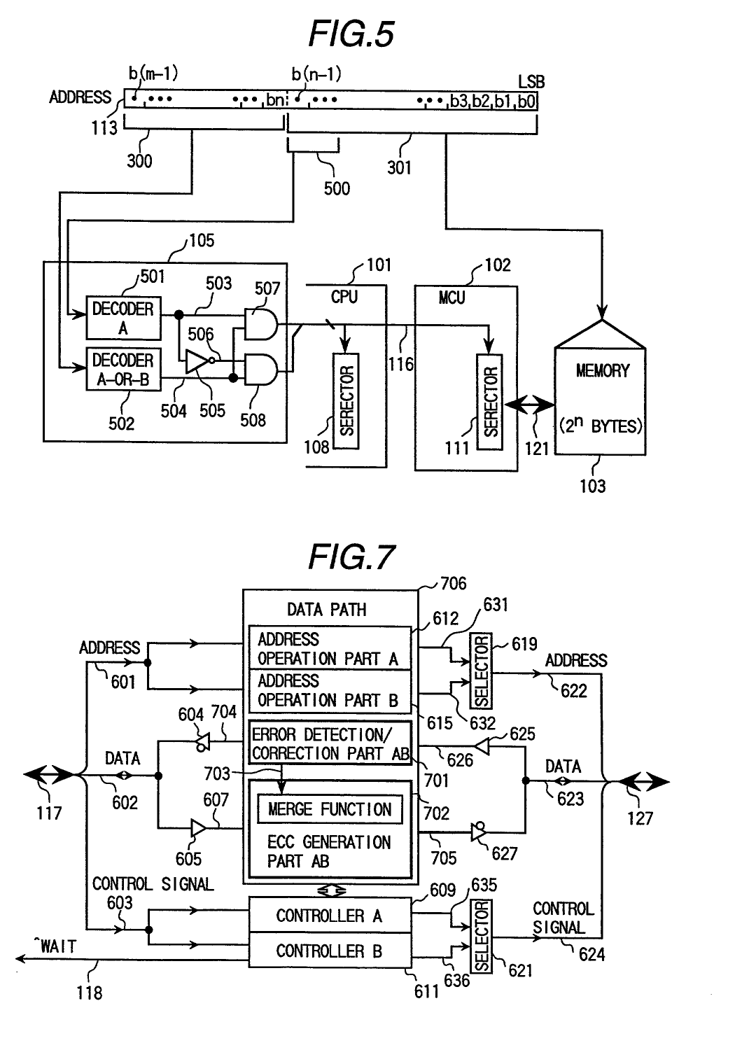

FIG. 5 is a block diagram showing how the decoding circuit 105 is used to implement the address space assignments sketched in FIG. 4. In FIG. 5, the address 113 is a byte address that is M bits long. The memory 103 has a capacity of 2ⁿ bytes. A specific byte address in the area 202 (FIG. 4) of the memory 103 is designated by bits 301 ranging from b0 (least significant bit (LSB)) to bit b(n−1). Bits 300 ranging from bit bn to bit b(m−1) designate a region that combines the address space areas A 400 and B 401. A decoder A-or-B 502 identifies the area A or B.

A decoder A 501 is used to identify the area A in the space 202 (FIG. 4) of the memory 103. This decoder admits those bits 500 (as many as needed) which are less significant than bit b(n−1) in the address 113.

The AND (507) of an output 503 from the decoder A 501 and an output 504 from the decoder A-or-B 502 indicates the area A. An output 506 is the NOT (505) of the output 503 from the decoder A 501. The AND (507) of the output 506 and the output 504 from the decoder A-or-B 502 designates the area B.

Using the arrangements described above, the second embodiment is capable of containing memory space within the real memory area 202.

(Third Embodiment)

FIG. 18 is a block diagram showing a typical constitution of another embodiment of the invention. What is different from the structure of FIG. 1 is the way in which burst access mode or single access mode is selected. The constitution of FIG. 18 uses programs means to provide a basis for judging the mode to be selected. Data for the judgment is set to a register 1800. An output 1801 of the register 1800 gives instructions to the selectors 108 and 111. Unlike in the first embodiment, the memory mapping of the third embodiment need not be recognized in address space.

The register 1800 is given the setting causing high-speed burst access mode to be selected for ordinary operations. When a partial write operation is judged to be needed, the register 1800 is given a setting for selecting single access mode. This allows a partial write operation to be carried out. With the partial write operation executed, the register 1800 is given another setting to restore burst access mode for ordinary operations.

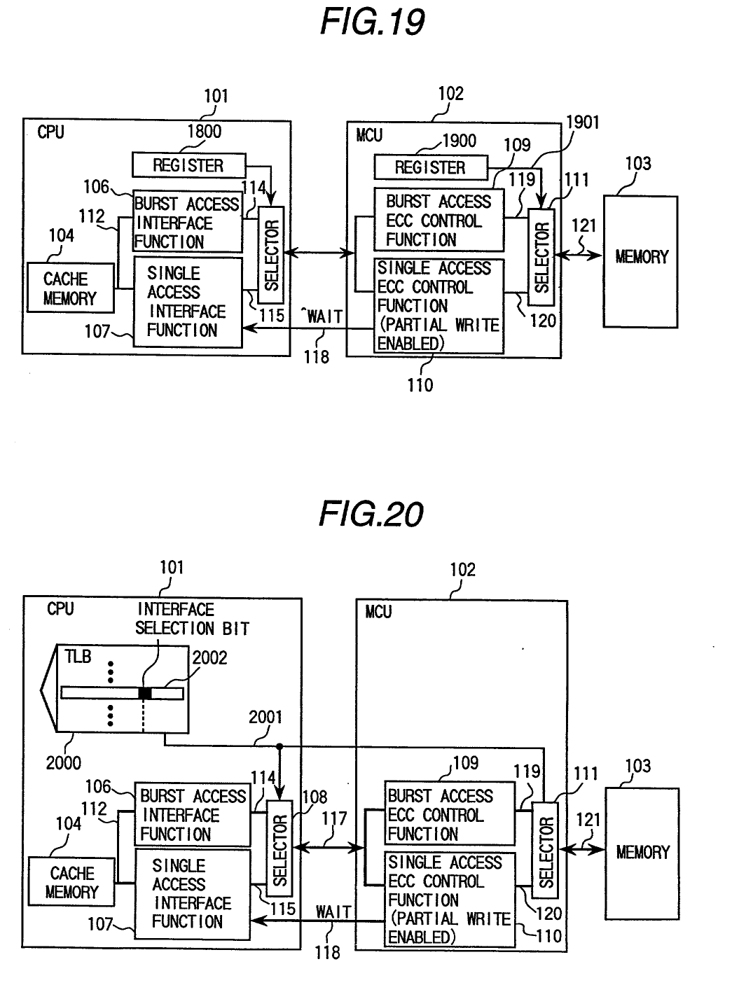

FIG. 19 depicts a variation of the constitution shown in FIG. 18. What is different from the setup of FIG. 18 is the provision of a register 1900, equivalent to the register 1800, within the MCU 102. An output 1901 of the register 1900 gives instructions to the selector 111 of the MCU 102. The structure of FIG. 19 is advantageous in that it eliminates the need for bringing the output 1801 of the register 1800 to the outside.

The registers 1800 and 1900 are usually given settings selecting high-speed burst access mode for ordinary operations. When a partial write operation is judged to be needed, the registers 1800 and 1900 are given settings for selecting single access mode. This allows the partial write operation to be carried out. Thereafter, the registers 1800 and 1900 are given settings that restore burst access mode for ordinary operations.

(Fourth Embodiment)

FIG. 20 is a block diagram depicting a typical configuration of an even further embodiment of the invention. What is different from the structure of FIG. 1 is the way in which burst access mode or single access mode is selected. The CPU has a TLB (translation look-aside buffer) 2000 that implements a virtual memory. The TLB 2000 has within its entries address translation tables for translating logical addresses to physical addresses in increments of four-kilobyte pages. Each address translation table in the TLB is provided with an interface selection bit. An output 2001 of the bit from each table is arranged to give instructions to the selectors 108 and 111.

Some pages may require a partial write operation. In that case, the interface selection bit in question is set so as to select single access mode when an address translation table is stored into a TLB entry.

1. An information processing apparatus comprising at least a memory, a CPU, a memory controller for controlling data read and write operations between said memory and said CPU, and selecting means;
wherein said CPU has first and second data transfer means, said first data transfer means transferring data in increments of M bits, said second data transfer means transferring data in increments of N bits, M being greater than N;
wherein said memory controller has first and second error detecting means, said first error detecting means corresponding to said first data transfer means and detecting an error in M-bit-long data, said second error detecting means corresponding to said second data transfer means and detecting an error in N-bit-long data; and
wherein said selecting means selects one of said first and said second data transfer means in accordance with an address generated for access to said memory.

2. The information processing apparatus according to claim 1, wherein said first data transfer means transfers data in burst access mode and wherein said second data transfer means transfers data in single access mode.

3. An information processing apparatus comprising:
a CPU having a first and a second data transfer interface, said first data transfer interface transferring data in a predetermined mode, said second data transfer interface transferring data in a mode different from said predetermined mode;
a memory controller having first and second error detecting and controlling means corresponding to said first and said second data transfer interface respectively, said memory controller controlling data write and read operations between a memory and said CPU; and
selecting means for assigning said first and said second error detecting and controlling means to different address spaces and for selecting one of said first and said second error detecting and controlling means in accordance with an address generated for access to said memory;
wherein said memory is accessed by one of said first and said second error detecting and controlling means selected on the basis of an output from said selecting means.

4. The information processing apparatus according to claim 3, wherein, upon access to said memory for writing target data thereto, said first and said second error detecting and controlling means add an error correcting code made of predetermined bits to said target data and then write said target data together with the added error correcting code to said memory; and wherein, upon access to said memory for reading data therefrom, said first and said second error detecting and controlling means check for and correct any error in the read-out data based on the error correcting code included in said read-out data.

5. The information processing apparatus according to claim 4, wherein said first error detecting and controlling means performs processing in fixed cycles, and said second error detecting means carries out processing in variable cycles.

6. The information processing apparatus according to claim 3, wherein said first and said second data transfer interface constitute a burst access interface and a single access interface respectively.

7. The information processing apparatus according to claim 6, wherein said first data transfer interface outputs a row address and a column address to said memory controller on a time division basis.

8. The information processing apparatus according to claim 4, wherein said CPU gains access to said memory in increments of N bits, and wherein, on writing target data of less than N bits to said memory, said second error detecting and controlling means embeds said target data into N-bit data read from said memory and adds an error correcting code to said N-bit data embedded with said target data.

9. An information processing apparatus at least comprising:
a CPU having a first data transfer interface for transferring data in a predetermined mode, a second data transfer interface for transferring data in a mode different from said predetermined mode, and an address translation table used to translate logical addresses to physical addresses and including information for designating one of said first and said second data transfer interface;
a memory controller having first and second error detecting and controlling means corresponding to said first and said second data transfer interface respectively, said memory controller controlling data read and write operations between a memory and said CPU; and
selecting means for selecting one of said first and said second error detecting and controlling means in accordance with the designating information included in said address translation table corresponding to an address generated for access to said memory;
wherein said memory is accessed by one of said first and said second error detecting and controlling means selected on the basis of an output from said selecting means.

10. An information processing apparatus according to claim 9, wherein, upon access to said memory for writing target data thereto, said first and said second error detecting and controlling means add an error correcting code made of predetermined bits to said target data and then write said target data together with the added error correcting code to said memory; and wherein, upon access to said memory for reading data therefrom, said first and said second error detecting and controlling means check for and correct any error in the read-out data based on the error correcting code included in said read-out data.

11. An information processing apparatus according to claim 10, wherein said first error detecting and controlling means performs processing in fixed cycles, and said second error detecting and controlling means carries out processing in variable cycles.

12. An information processing apparatus according to claim 9, wherein said first and said second data transfer interface constitute a burst access interface and a single access interface respectively.

13. An information processing apparatus according to claim 12, wherein said first data transfer interface outputs a row address and a column address to said memory controller on a time division basis.

14. An information processing apparatus according to claim 10, wherein said CPU gains access to said memory in increments of N bits, and wherein, on writing target data of less than N bits to said memory, said second error detecting and controlling means embeds said target data into N-bit data read from said memory and adds an error correcting code to said N-bit data embedded with said target data.
